(19) United States
(12) Patent Application Publication
(10) Pub. No.: US 2016/0172279 A1
(43) Pub. Date: Jun. 16, 2016

(54) Integrated Power Assembly with Reduced Form Factor and Enhanced Thermal Dissipation

(71) Applicant: Infineon Technologies Americas Corp., El Segundo, CA (US)

(72) Inventor: Eung San Cho, Torrance, CA (US)

(73) Assignee: INFINEON TECHNOLOGIES AMERICAS CORP.

(21) Appl. No.: 14/938,671

(22) Filed: Nov. 11, 2015

Related U.S. Application Data
(60) Provisional application No. 62/090,202, filed on Dec. 10, 2014.

(51) Int. Cl. H01L 23/495; H01L 23/31; H01L 29/778; H01L 29/20; H01L 29/739; H01L 29/78; H02M 3/158; H01L 29/16

(52) U.S. Cl. CPC H01L 23/49568; H02M 3/158; H01L 23/4951; H01L 23/49537; H01L 23/49562; H01L 23/49575; H01L 23/49582; H01L 23/3114; H01L 29/16; H01L 29/2003; H01L 29/7397; H01L 29/7813; H01L 29/7787

(57) ABSTRACT

An integrated power assembly is disclosed. The integrated power assembly includes a printed circuit board, a first leadframe having partially etched segments and non-etched segments on the printed circuit board, a first semiconductor die configured for attachment to the partially etched segments of the first leadframe, a second leadframe having a legless conductive clip, and a second semiconductor die situated over the first semiconductor die and being coupled to the first semiconductor die by the legless conductive clip.

The present application claims the benefit of and priority to a provisional patent application entitled “Dual Gauge for Stacked Power Devices,” Ser. No. 62/090,202 filed on Dec. 10, 2014. The disclosure in this provisional application is hereby incorporated fully by reference into the present application.

### BACKGROUND

Power converters, such as buck converters, are commonly utilized to convert a high DC voltage to a low DC voltage. A power converter typically includes a high-side switch and a low-side switch connected in a half-bridge configuration and controlled by a driver integrated circuit (IC). To improve form factor, electrical and thermal performances, and manufacturing cost, it is often desirable to integrate components of a power converter circuit, such as a half-bridge based DC-DC converter or a voltage converter, into a power semiconductor package.

In a conventional power semiconductor package, individual semiconductor dies are arranged side by side and coupled to a shared support surface, such as a printed circuit board (PCB), through their respective conductive clips. However, the routing between semiconductor dies through the conductive clips and the PCB can undesirably increase electrical resistance. Also, the form factor of the laterally arranged individually packaged semiconductor dies requires significant area to be reserved on the PCB. Moreover, power devices often generate significant heat during operation, which can cause their temperature to rise outside of the suitable temperature range if the heat is not sufficiently dissipated from the power devices.

Thus, there is a need in the art to provide an integrated power assembly with reduced form factor and enhanced thermal dissipation.

### SUMMARY

The present disclosure is directed to an integrated power assembly with reduced form factor and enhanced thermal dissipation, substantially as shown in and/or described in connection with at least one of the figures, and as set forth in the claims.

### BRIEF DESCRIPTION OF THE DRAWINGS

FIG. 1A illustrates an exemplary circuit diagram of a power converter, according to one implementation of the present application.

FIG. 1B illustrates an exemplary circuit diagram of a composite switch, according to one implementation of the present application.

FIG. 2A illustrates a cross-sectional view of an exemplary integrated power assembly of a power switching stage, according to one implementation of the present application.

FIG. 2B illustrates a cross-sectional view of an exemplary integrated power assembly of a power switching stage, according to one implementation of the present application.

FIG. 3 illustrates a perspective view of a three-phase inverter, according to one implementation of the present application.

FIG. 4 illustrates a cross-sectional view of integrated power assembly of a composite switch, according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

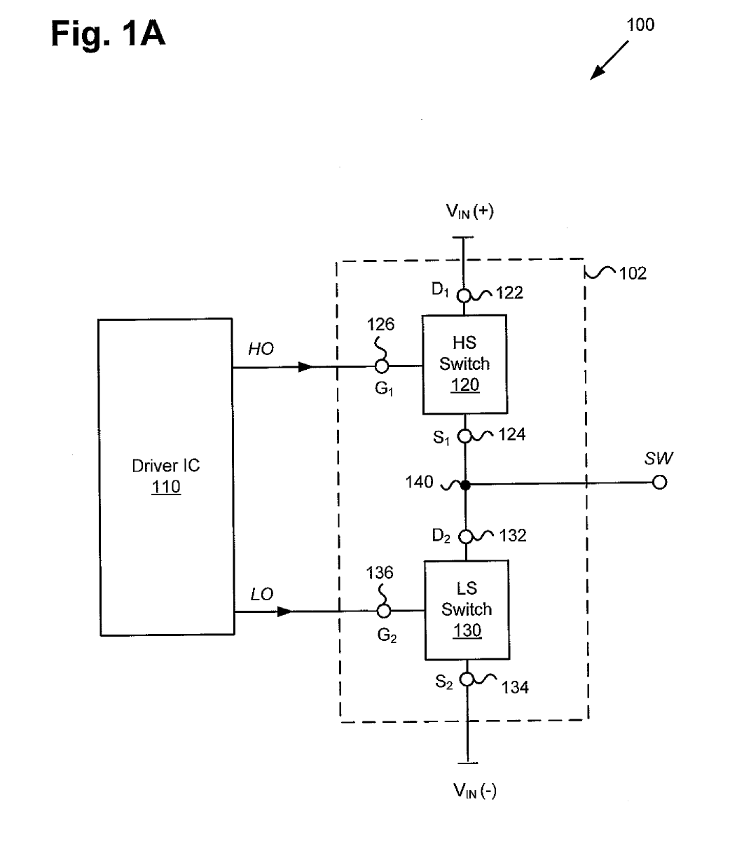

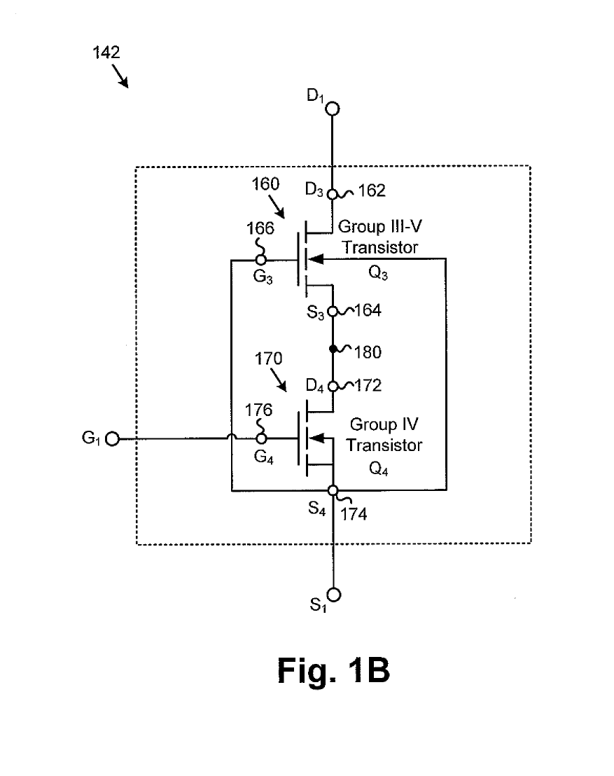

FIG. 1A illustrates a circuit schematic of an exemplary power conversion circuit, in accordance with an implementation of the present application. As shown in FIG. 1A, power conversion circuit 100 includes driver integrated circuit (IC) 110 and power switching stage 102 having high-side switch 120 and low-side switch 130. Driver IC 110 is configured to provide high-side drive signal HO and low-side drive signal LO, which are gate drive signals, to drive respective high-side switch 120 and low-side switch 130 of power switching stage 102. In power switching stage 102, high-side switch 120 and low-side switch 130 are coupled between positive input terminal V_{IN(+)} and negative input terminal V_{IN(-)}, and switched node 140 as an output node is between high-side switch 120 and low-side switch 130.

As illustrated in FIG. 1A, high-side switch 120 (e.g., Q₁) includes a control transistor having drain 122 (e.g., D₁), source 124 (e.g., S₁) and gate 126 (e.g., G₁). Low-side switch 130 (e.g., Q₂) includes a synchronous (hereinafter “sync”) transistor having drain 132 (e.g., D₂), source 134 (e.g., S₂) and gate 136 (e.g., G₂). Drain 122 of high-side switch 120 is coupled to positive input terminal V_{IN(+)}, while source 124 of high-side switch 120 is coupled to switched node 140. Gate 126 of high-side switch 120 is coupled to driver IC 110, which provides high-side drive signal HO to gate 126. As illustrated in FIG. 1A, drain 132 of low-side switch 130 is coupled to switched node 140, while source 134 of low-side switch 130 is coupled to negative input terminal V_{IN(-)}. Gate 136 of low-side switch 130 is coupled to driver IC 110, which provides low-side drive signal LO to gate 136.

In an implementation, at least one of high-side switch 120 and low-side switch 130 includes a group IV semiconductor device, such as a silicon metal-oxide-semiconductor field effect transistor (MOSFET). In another implementation, at least one of high-side switch 120 and low-side switch 130 includes a group III-V semiconductor device, such as a gallium nitride (GaN) device, which can be a GaN high electron mobility transistor (HEMT). In other implementations, high-side switch 120 and low-side switch 130 may be any other suitable semiconductor devices, such as bipolar junction transistors (BJTs) and insulated gate bipolar transistors (IGBTs).

In an implementation, high-side switch 120 and low-side switch 130 (also referred to as power switch 120 and power switch 130, respectively) may each include a group III-V semiconductor device, such as a III-Nitride transistor. By including at least one III-Nitride transistor in power switching stage 102, power conversion circuit 100 may exploit the high breakdown fields, high saturation velocities, and two-dimensional electron gases (2DEGs) offered by III-Nitride materials. It may be desirable to couple the at least one III-Nitride transistor to a group IV transistor (e.g., a silicon transistor). For example, it may be desirable for the at least one III-Nitride transistor, to operate as an enhancement mode device in power conversion circuit 100. This may be accomplished by coupling the at least one III-Nitride transistor, such as a depletion mode GaN transistor, in cascode with a group IV transistor to produce an enhancement mode composite switch, such as enhancement mode composite switch 142 in FIG. 1B.

Referring now to FIG. 1B, FIG. 1B illustrates an exemplary circuit diagram of a composite switch having a group III-V transistor in cascode with a group IV transistor, in accordance with one implementation of the present application. Enhancement mode composite switch 142 includes composite source S₁, composite gate G₁ and composite drain D₁. Enhancement mode composite switch 142 may correspond to at least one of high-side switch 120 and low-side switch 130 in FIG. 1A. For example, while one enhancement mode composite switch 142 may be utilized as high-side switch 120, another enhancement mode composite switch 142 may be utilized as low-side switch 130 in power conversion circuit 100 in FIG. 1A. Thus, composite source S₁, composite gate G₁ and composite drain D₁ of enhancement mode composite switch 142 may correspond to source 124 (e.g., S₁), gate 126 (e.g., G₁) and drain 122 (e.g., D₁), respectively, of high-side switch 120. Composite source S₁, composite gate G₁ and composite drain D₁ of enhancement mode composite switch 142 may also correspond to source 134 (e.g., S₂), gate 136 (e.g., G₂) and drain 132 (e.g., D₂), respectively, of low-side switch 130.

As illustrated in FIG. 1B, enhancement mode composite switch 142 includes group III-V transistor 160 in cascode with group IV transistor 170. For example, group III-V transistor 160 may be a III-Nitride heterojunction field-effect transistor (HFET), such as a GaN HEMT. In the present implementation, group III-V transistor 160 is a depletion mode transistor, such as a depletion mode GaN transistor. Group IV transistor 170 may be a silicon based power semiconductor device, such as a silicon power MOSFET. In the present implementation, group IV transistor 170 is an enhancement mode transistor, such as an enhancement mode silicon transistor.

As illustrated in FIG. 1B, group III-V transistor 160 (e.g., Q₃) includes drain 162 (e.g., D₃), source 164 (e.g., S₃)and gate 166 (e.g., G₃). Group IV transistor 170 (e.g., Q₄) includes drain 172 (e.g., D₄), source 174 (e.g., S₄) and gate 176 (e.g., G₄). Drain 162 of group III-V transistor 160 is coupled to composite drain D₁, while source 164 of group III-V transistor 160 is coupled to switched node 180. Gate 166 of group III-V transistor 160 is coupled to source 174 of group IV transistor 170. As illustrated in FIG. 1B, drain 172 of group IV transistor 170 is coupled to switched node 180, while source 174 of group IV transistor 170 is coupled to composite source S₁. Gate 176 of group IV transistor 170 is coupled to composite gate G₁.

In enhancement mode composite switch 142, drain 172 of group IV transistor 170 is connected to source 164 of group III-V transistor, such that both devices will be in blocking mode under a reverse voltage condition. As configured, group IV transistor 170 may be a low voltage device while group III-V transistor 160 may be a high voltage device. In enhancement mode composite switch 142, gate 166 of group III-V transistor 160 is connected to source 174 of group IV transistor 170. Thus, group III-V transistor 160 may be off absent a bias voltage on gate 176 of group IV transistor 170, such that enhancement mode composite switch 142 is a normally OFF device.

According to an implementation of the present application, group 111-V transistor 160 and group IV transistor 170 may be coupled together on a printed circuit board (PCB) in an integrated power assembly. According to an implementation of the present application, group IV transistor 170 is on a group IV semiconductor die situated on a PCB, and group 111-V transistor 160 is on a group III-V semiconductor die situated over the group IV semiconductor die. Group III-V transistor 160 may be coupled to group IV transistor 170 in an integrated power assembly, which can provide reduced form factor and enhanced thermal dissipation.

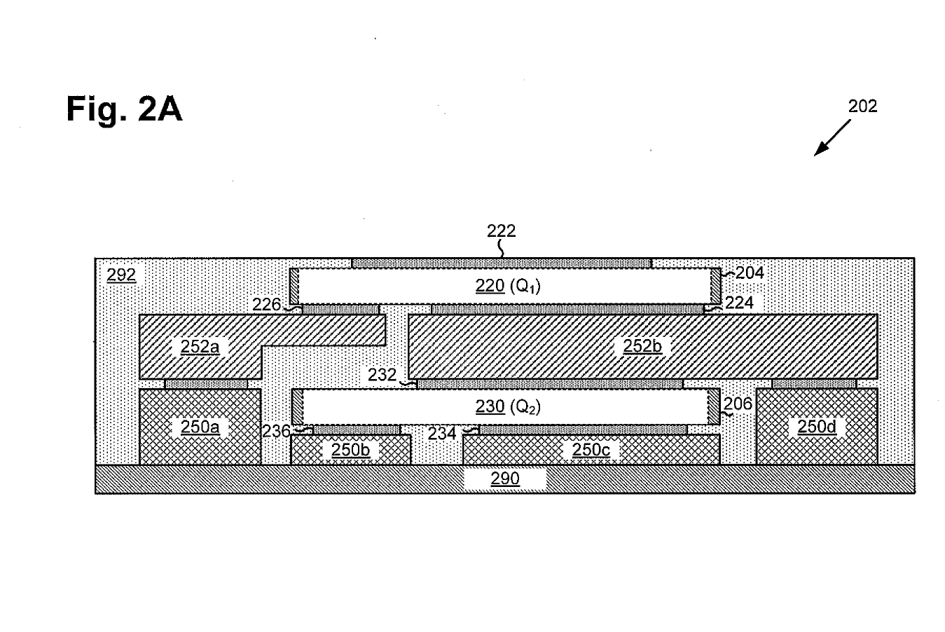

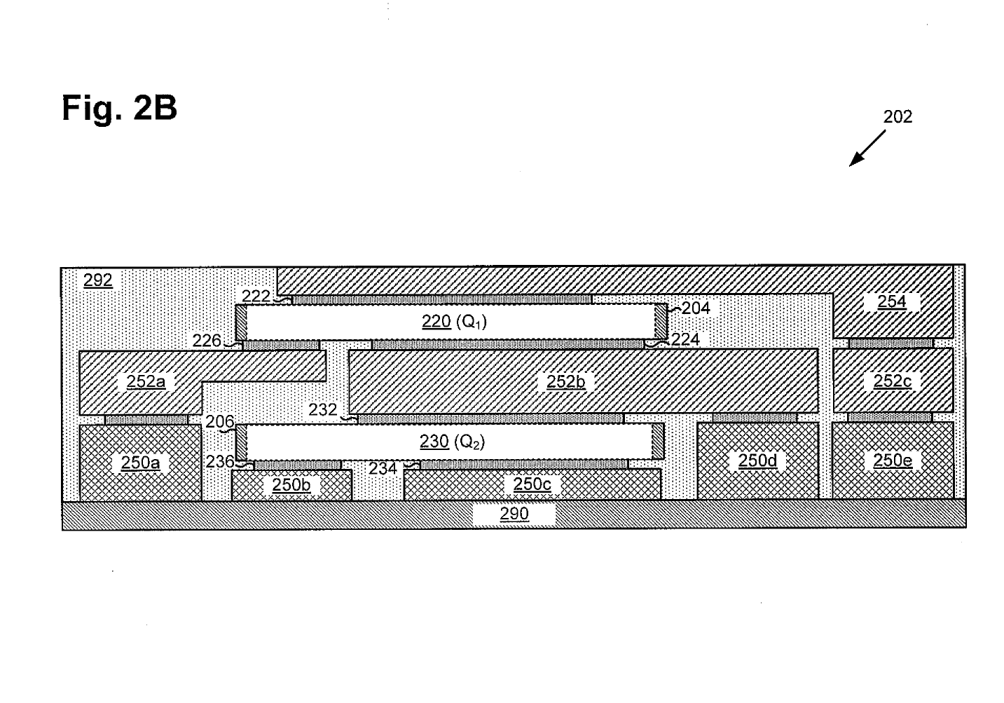

Referring now to FIG. 2A, FIG. 2A illustrates a cross-sectional view of an exemplary integrated power assembly of a power switching stage, according to one implementation of the present application. As illustrated in FIG. 2A, integrated power assembly 202 includes semiconductor die 204 having power switch 220, semiconductor die 206 having power switch 230, leadframe 250 having non-etched segments 250a and 250d and partially etched segments 250b and 250c on substrate 290, and leadframe 252 having partially etched conductive clip 252a and legless conductive clip 252b. Also, integrated power assembly 202 may optionally include molding compound 292. In the present implementation, power switches 220 and 230 may correspond to high-side switch 120 and low-side switch 130, respectively, in power conversion circuit 100 of FIG. 1A, and may be connected as such.

As illustrated in FIG. 2A, semiconductor die 204 includes power switch 220. In an implementation, power switch 220 may correspond to high-side switch 120 in power conversion circuit 100 of FIG. 1A. Power switch 220 includes a control transistor having power electrode 222 (e.g., drain electrode) situated on a top surface of semiconductor die 204, and power electrode 224 (e.g., source electrode) and control electrode 226 (e.g., gate electrode) situated on a bottom surface of semiconductor die 204. Control electrode 226 (e.g., gate electrode) of power switch 220 is electrically and mechanically coupled to a top surface of partially etched conductive clip 252a, which is in turn electrically coupled to substrate 290 through non-etched segment 250a of leadframe 250. Power electrode 224 (e.g., source electrode) of power switch 220 is electrically and mechanically coupled to a top surface of legless conductive clip 252b, which is in turn electrically coupled to substrate 290 through non-etched segment 250d of leadframe 250. As illustrated in FIG. 2A, power electrode 222 (e.g., drain electrode) of power switch 220 is exposed on a top surface of integrated power assembly 202. Power electrode 222 may include a solderable front metal, such as titanium, copper, nickel or silver. Since molding compound 292 does not cover the top surface of power electrode 222, power switch 220 is configured to be affixed (e.g., soldered) to a power bus, which may function as a heatsink to dissipate heat generated from integrated power assembly 202 during operation.

As illustrated in FIG. 2A, leadframe 252 includes partially etched conductive clip 252a and legless conductive clip 252b. Partially etched conductive clip 252a is electrically and mechanically coupled to control electrode 226 of power switch 220, while legless conductive clip 252b is electrically and mechanically coupled to power electrode 224 of power switch 220. Partially etched conductive clip 252a and legless conductive clip 252b have a substantially coplanar top surface, and provide structural support for semiconductor die 204. As illustrated in FIG. 2A, partially etched conductive clip 252a has a non-etched portion and a partially etched portion, where the non-etched portion retains a full thickness of leadframe 252 and the partially etched portion has a thickness that is a fraction of the full thickness of leadframe 252. Partially etched conductive clip 252a is configured to provide clearance between semiconductor die 206 and leadframe 252, such that control electrode 226 on semiconductor die 204 is not electrically shorted to semiconductor die 206. Legless conductive clip 252b is physically separated from partially etched conductive clip 252a, and has a substantially flat body having a substantially uniform thickness, which is the full thickness of leadframe 252.

In the present implementation, partially etched conductive clip 252a and legless conductive clip 252b are made of the same material, and have a substantially uniform composition. In another implementation, partially etched conductive clip 252a and legless conductive clip 252b can be made of different materials, and have different compositions. In the present implementation, partially etched conductive clip 252a and legless conductive clip 252b of leadframe 252 include copper. In another implementation, partially etched conductive clip 252a and legless conductive clip 252b may include other suitable conductive materials, such as aluminum or tungsten.

As illustrated in FIG. 2A, semiconductor die 206 includes power switch 230. In an implementation, power switch 230 may correspond to low-side switch 130 in power conversion circuit 100 of FIG. 1A. Power switch 230 includes a sync transistor having power electrode 232 (e.g., drain electrode) situated on a top surface of semiconductor die 206, and power electrode 234 (e.g., source electrode) and control electrode 236 (e.g., gate electrode) situated on a bottom surface of semiconductor die 206.

As illustrated in FIG. 2A, semiconductor die 204 is situated on leadframe 252 over semiconductor die 206. Power electrode 224 (e.g., source electrode) of power switch 220 is electrically coupled to power electrode 232 (e.g., drain electrode) of power switch 230 through legless conductive clip 252b, which may correspond to switched node 140 in FIG. 1A. Control electrode 236 (e.g., gate electrode) and power electrode 234 (e.g., source electrode) of power switch 230 are electrically and mechanically coupled to partially etched segments 250b and 250c, respectively, of leadframe 250 situated on substrate 290. In an implementation, substrate 290 may be a circuit board, such as a printed circuit board (PCB), or any other suitable substrate.

As illustrated in FIG. 2A, leadframe 250 includes non-etched segments 250a and 250d, and partially etched segments 250b and 250c. Non-etched segments 250a and 250d, and partially etched segments 250b and 250c are different portions of leadframe 250, where non-etched segments 250a and 250d retain a full thickness of leadframe 250, and partially etched segments 250b and 250c are etched, thus having a fraction of the full thickness of leadframe 250 (e.g., a half or a quarter of the thickness of non-etched segment 250a). Non-etched segments 250a and 250d, and partially etched segments 250b and 250c are physically separated from one another. In the present implementation, non-etched segments 250a and 250d, and partially etched segments 250b and 250c are made of the same material, and have a substantially uniform composition. In the present implementation, non-etched segments 250a and 250d, and partially etched segments 250b and 250c of leadframe 250 may include a metal, such as copper, aluminum, or tungsten, a metal alloy, a tri-metal or other conductive material. In another implementation, non-etched segments 250a and 250d, and partially etched segments 250b and 250c can be made of different materials, and have different compositions. In the present implementation, partially etched segments 250b and 250c have a substantially uniform thickness that is a fraction of the full thickness of leadframe 250. In another implementation, partially etched segments 250b and 250c can have different thicknesses.

As illustrated in FIG. 2A, since semiconductor die 206 is situated on partially etched segments, as opposed to non-etched segments, of leadframe 250, the overall height of semiconductor die 206 in integrated power assembly 202 can be reduced, such that the leg portion employed in conventional conductive clips can be eliminated. In the present implementation, legless conductive clip 252b has a substantially flat body without a leg portion. In contrast to conventional power semiconductor packages having semiconductor dies attached to non-etched lead segments and conductive clips with leg portions, implementations of the present application utilize non-etched segment 250d and partially etched segments 250b and 250c of leadframe 250 to enable semiconductor die 206 to couple to substrate 290 using legless conductive clip 252b. As a result, the overall height of integrated power assembly 202 can be reduced, which in turn reduces the form factor of integrated power assembly 202. In one implementation, semiconductor dies 204 and 206 may each have a thickness of 70 μm (i.e., 70*10⁻⁶ meters) or less, and integrated power assembly 202 may have an overall height of 0.8 mm (i.e., 0.8*10⁻³ meters) or less. Also, by employing legless conductive clip 252b and semiconductor die 206 configured for attachment to partially etched segments 250b and 250c, the thickness of legless conductive clip 252b can be adjusted to improve high current and voltage handling capability to suit the needs of a particular implementation without significantly affecting the overall height of integrated power assembly 202. In contrast to conventional power semiconductor packages having individual semiconductor dies arranged side by side and coupled to a substrate through their respective conductive clips, by stacking semiconductor die 204 over semiconductor die 206 on substrate 290, integrated power assembly 202 can advantageously have a reduced footprint, thereby reducing the form factor of integrated power assembly 202.

In an implementation, integrated power assembly 202 having power switches 220 and 230 connected in a half-bridge may correspond to one phase of a three-phase inverter, or more generally a polyphase inverter, which can be used to drive a motor, for example. For example, in integrated power assembly 202, power switch 220 (e.g., a high-side switch) and power switch 230 (e.g., a low-side switch) are connected in a half-bridge, which may be coupled between a high side power bus (e.g., positive input terminal V_{IN(+)} in FIG. 1A) and a low side power bus (e.g., negative input terminal V_{IN(-)} in FIG. 1A) with legless conductive clip 252b of leadframe 252 between power switches 220 and 230 as an output terminal (e.g., switched node 140 in FIG. 1A).

Referring now to FIG. 2B, FIG. 2B illustrates a cross-sectional view of an exemplary integrated power assembly, according to one implementation of the present application. With similar numerals representing similar features in FIG. 2A, integrated power assembly 202 in FIG. 2B includes semiconductor die 204 having power switch 220, semiconductor die 206 having power switch 230, leadframe 250 having non-etched segments 250a and 250d, and partially etched segments 250b and 250c on substrate 290, leadframe 252 having partially etched conductive clip 252a and legless conductive clip 252b, and molding compound 292. In addition, integrated power assembly 202 in FIG. 2B includes non-etched segment 250e in leadframe 250, non-etched segment 252c in leadframe 252, and partially etched conductive clip 254, where power electrode 222 (e.g., drain electrode) of power switch 220 is coupled to substrate 290 through partially etched conductive clip 254, non-etched segment 252c and non-etched segment 250e.

As illustrated in FIG. 2B, molding compound 292 covers semiconductor die 204, semiconductor die 206, leadframe 250 having non-etched segments 250a, 250d and 250e, and partially etched segments 250b and 250c, and leadframe 252 having partially etched conductive clip 252a, legless conductive clip 252b and non-etched segment 252c. Partially etched conductive clip 254 is electrically and mechanically coupled to power electrode 222 (e.g., drain electrode) of power switch 220, and is exposed at the top surface of integrated power assembly 202. As such, partially etched conductive clip 254 can be used, as a power bus, to supply a high-side power bus voltage to power switch 220. Also, as the large top surface of partially etched conductive clip 254 is exposed (i.e., not covered by molding compound 292), partially etched conductive clip 254 can function as a heatsink to provide enhanced thermal dissipation by radiating heat directly to ambient air, for example. In another implementation, molding compound 292 may cover and fully embed semiconductor dies 204 and 206, leadframes 250 and 252, and partially etched conductive clip 254.

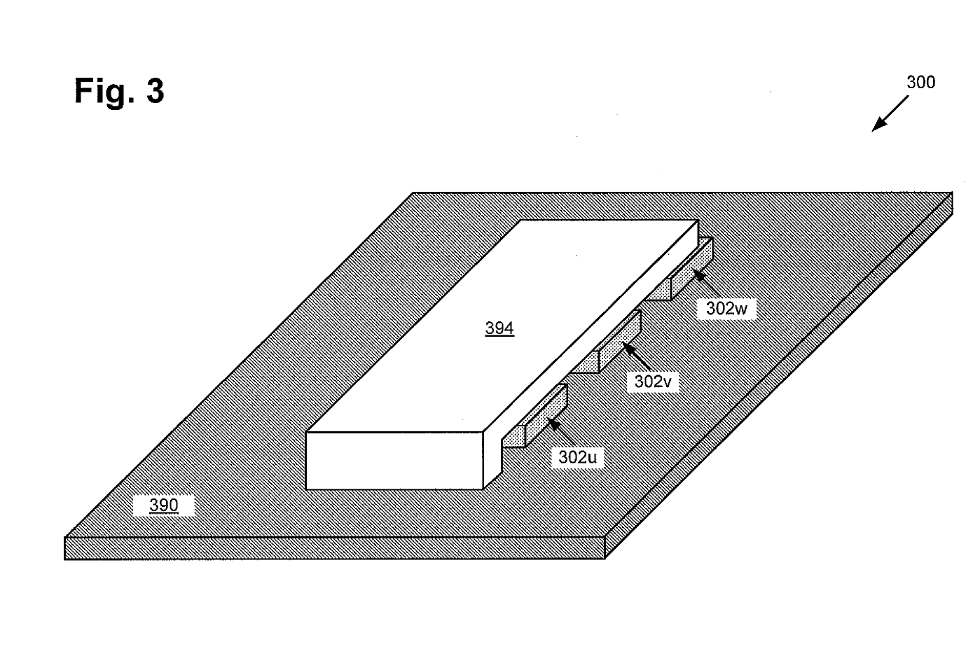

Referring now to FIG. 3, FIG. 3 illustrates a perspective view of a three-phase inverter, in accordance with an implementation of the present application. As illustrated in FIG. 3, three-phase inverter 300 includes integrated power assemblies 302u, 302v and 302w formed on substrate 390 and coupled to power bus 394. In one implementation, integrated power assemblies 302u, 302v and 302w may be a U-phase, a V-phase and a W-phase, respectively, of three-phase inverter 300, which can be used to drive a motor, for example. Each of integrated power assemblies 302u, 302v and 302w in FIG. 3 may correspond to integrated power assembly 202 in FIG. 2A. For example, each of integrated power assemblies 302u, 302v and 302w may include a high-side switch (e.g., power switch 220 in FIG. 2A) and a low-side switch (e.g., power switch 230 in FIG. 2A) connected in a half-bridge in an integrated power assembly (e.g., integrated power assembly 202 in FIG. 2A). Thus, each of integrated power assemblies 302u, 302v and 302w includes a power electrode, such as power electrode 222 (e.g., drain electrode) in FIG. 2A, exposed on a top surface thereof. Power bus 394 is configured to be affixed to, and provide a high side bus voltage to, the exposed power electrode (not explicitly shown in FIG. 3) in each of integrated power assemblies 302u, 302v and 302w. Moreover, since power bus 394 has a large exposed area on its top surface, power bus 394 can function as a common heatsink for integrated power assemblies 302u, 302v and 302w to provide enhanced thermal dissipation by radiating heat directly to ambient air, for example.

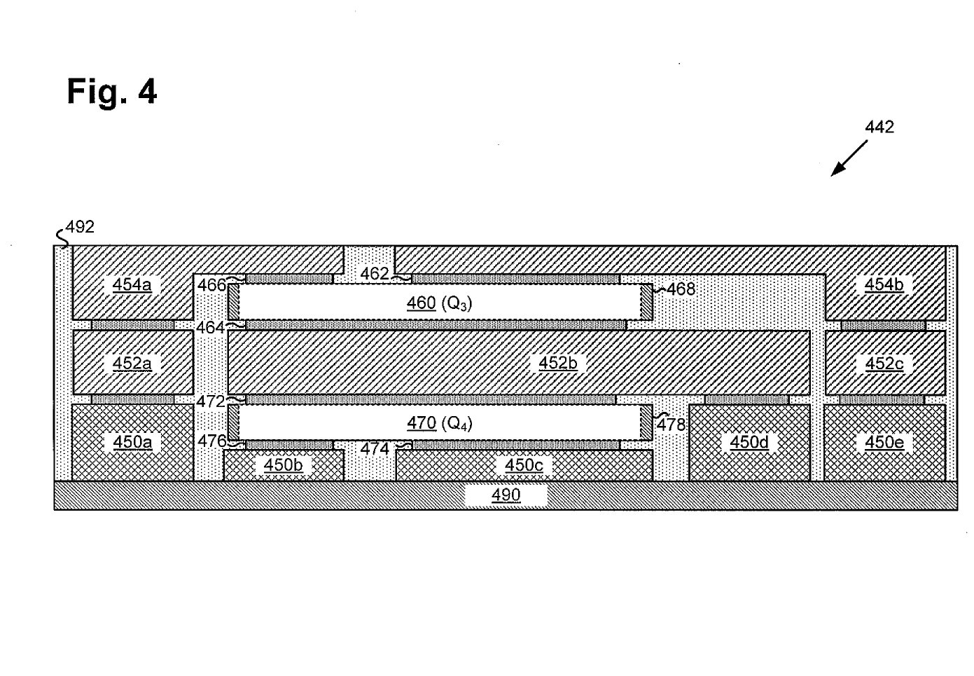

Referring now to FIG. 4, FIG. 4 illustrates a cross-sectional view of integrated power assembly of a composite switch, according to one implementation of the present application. As illustrated in FIG. 4, integrated power assembly 442 may include a composite switch, such as enhancement mode composite switch 142 in FIG. 1B, which may correspond to at least one of high-side switch 120 and low-side switch 130 in FIG. 1A. For example, while one integrated power assembly 442 may be utilized as high-side switch 120, another integrated power assembly 442 may be utilized as low-side switch 130 in power conversion circuit 100.

As illustrated in FIG. 4, integrated power assembly 442 includes semiconductor die 468 having power switch 460, semiconductor die 478 having power switch 470, leadframe 450 having non-etched segments 450a, 450d and 450e, and partially etched segments 450b and 450c on substrate 490, leadframe 452 having non-etched segments 452a and 452c, and legless conductive clip 452b, and leadframe 454 having partially etched conductive clips 454a and 454b. In the present implementation, power switches 460 and 470 may correspond to group III-V transistor 160 and group IV transistor 170, respectively, as shown in FIG. 1B, and may be connected as such.

As illustrated in FIG. 4, semiconductor die 468 includes power switch 460. For example, power switch 460 may be a III-Nitride HFET, such as a GaN HEMI. In the present implementation, power switch 460 is a depletion mode transistor, such as a depletion mode GaN transistor. Power switch 470 may be a silicon based power semiconductor device, such as a silicon power MOSFET. In the present implementation, power switch 470 is an enhancement mode transistor, such as an enhancement mode silicon transistor.

As illustrated in FIG. 4, semiconductor die 468 having power switch 460 is situated on legless conductive clip 452b of leadframe 452 over semiconductor die 478 having power switch 470. Power switch 460 includes power electrode 462 (e.g., drain electrode) and control electrode 466 (e.g., gate electrode) situated on a top surface of semiconductor die 468, and power electrode 464 (e.g., source electrode) situated on a bottom surface of semiconductor die 468. Control electrode 466 (e.g., gate electrode) of power switch 460 is electrically coupled to substrate 490 through partially etched conductive clip 454a of leadframe 454, non-etched segment 452a of leadframe 452, and non-etched segment 450a of leadframe 450. Power electrode 462 (e.g., drain electrode) of power switch 460 is electrically coupled to substrate 490 through partially etched conductive clip 454b of leadframe 454, non-etched segment 452c of leadframe 452, and non-etched segment 450e of leadframe 450. Power electrode 464 (e.g., source electrode) of power switch 460 is electrically and mechanically coupled to a top surface of legless conductive clip 452b of leadframe 452.

As illustrated in FIG. 4, leadframe 452 includes non-etched segments 452a and 452c, and legless conductive clip 452b. Non-etched segment 452a is coupled between partially etched conductive clip 454a and non-etched segment 450a. Non-etched segment 452c is coupled between partially etched conductive clip 454b and non-etched segment 450e. Legless conductive clip 452b is electrically and mechanically coupled between power electrode 464 of power switch 460 and power electrode 472 of power switch 470. Non-etched segments 452a and 452c, and legless conductive clip 452b have a substantially coplanar top surface. Legless conductive clip 452b provides structural support for semiconductor die 468. Legless conductive clip 452b is physically separated from non-etched segments 452a and 452c, and has a substantially flat body having a substantially uniform thickness, which is the full thickness of leadframe 452.

As illustrated in FIG. 4, partially etched conductive clips 454a and 454b each have a non-etched portion and a partially etched portion, where the non-etched portion retains a full thickness of leadframe 454 and the partially etched portion has a thickness that is a fraction of the full thickness of leadframe 454. Partially etched conductive clip 454a is physically separated from partially etched conductive clip 454b, where partially etched conductive clips 454a and 454b are respectively coupled to control electrode 466 and power electrode 462 of power switch 460. As illustrated in FIG. 4, partially etched conductive clips 454a and 454b each include an exposed top surface. Since molding compound 492 does not cover the top surfaces of partially etched conductive clips 454a and 454b, the large exposed top surfaces of partially etched conductive clips 454a and 454b may each function as a heatsink to dissipate heat generated from integrated power assembly 442 during operation. In another implementation, molding compound 492 may cover and fully embed semiconductor dies 468 and 478, and leadframes 450, 452 and 454.

In the present implementation, partially etched conductive clips 454a and 454b are made of the same material, and have a substantially uniform composition. In another implementation, partially etched conductive clips 454a and 454b can be made of different materials, and have different compositions. In the present implementation, partially etched conductive clips 454a and 454b of leadframe 454 include copper. In another implementation, partially etched conductive clips 454a and 454b may include other suitable conductive materials, such as aluminum or tungsten. In the present implementation, partially etched conductive clips 454a and 454b of leadframe 454 are made of the same material as non-etched segments 452a and 452c, and legless conductive clip 452b of leadframe 452. In another implementation, partially etched conductive clips 454a and 454b of leadframe 454 and non-etched segments 452a and 452c, and legless conductive clip 452b of leadframe 452 can be made of different materials, and have different compositions.

As illustrated in FIG. 4, semiconductor die 478 includes power switch 470. For example, power switch 470 includes power electrode 472 (e.g., drain electrode) situated on a top surface of semiconductor die 478, and control electrode 476 (e.g., gate electrode) and power electrode 474 (e.g., source electrode) situated on a bottom surface of semiconductor die 478. Power electrode 472 (e.g., drain electrode) of power switch 470 is electrically and mechanically coupled to a bottom surface of legless conductive clip 452b, which is electrically and mechanically coupled to power electrode 464 (e.g., source electrode) of power switch 460 on its top surface. Legless conductive clip 452b, which may correspond to switched node 180 in FIG. 1B, is electrically coupled to substrate 490 through non-etched segment 450d of leadframe 450. Control electrode 476 (e.g., gate electrode) and power electrode 474 (e.g., source electrode) of power switch 470 are electrically and mechanically coupled to partially etched segments 450b and 450c, respectively, of leadframe 450 situated on substrate 490.

As illustrated in FIG. 4, leadframe 450 includes non-etched segments 450a, 450d and 450e, and partially etched segments 450b and 450c situated on substrate 490. Non-etched segments 450a, 450d and 450e, and partially etched segments 450b and 450c are different portions of leadframe 450, where non-etched segments 450a, 450d and 450e retain a full thickness of leadframe 450, and partially etched segments 450b and 450c are etched, thus having a fraction of the full thickness of leadframe 450 (e.g., a half or a quarter of the thickness of non-etched segment 450a). Non-etched segments 450a, 450d and 450e, and partially etched segments 450b and 450c are physically separated from one another. In the present implementation, non-etched segments 450a, 450d and 450e, and partially etched segments 450b and 450c are made of the same material, and have a substantially uniform composition. In the present implementation, non-etched segments 450a, 450d and 450e, and partially etched segments 450b and 450c of leadframe 450 may include a metal, such as copper, aluminum, or tungsten, a metal alloy, a tri-metal or other conductive material. In another implementation, non-etched segments 450a, 450d and 450e, and partially etched segments 450b and 450c can be made of different materials, and have different compositions. In the present implementation, partially etched segments 450b and 450c have a substantially uniform thickness that is a fraction of the full thickness of leadframe 450. In another implementation, partially etched segments 450b and 450c can have different thicknesses.

As illustrated in FIG. 4, since semiconductor die 478 is situated on partially etched segments, as opposed to non-etched segments, of leadframe 450, the overall height of semiconductor die 478 in integrated power assembly 442 can be reduced, such that the leg portion employed in conventional conductive clips can be eliminated. In the present implementation, legless conductive clip 452b has a substantially flat body without a leg portion. In contrast to conventional power semiconductor packages having semiconductor dies attached to non-etched lead segments and conductive clips with leg portions, implementations of the present application utilize non-etched segment 450d and partially etched segments 450b and 450c of leadframe 450 to enable semiconductor die 478 to couple to substrate 490 using legless conductive clip 452b. As a result, the overall height of integrated power assembly 442 can be reduced, which in turn reduces the form factor of integrated power assembly 442. Also, by employing legless conductive clip 452b and semiconductor die 478 configured for attachment to partially etched segments 450b and 450c, the thickness of legless conductive clip 452b can be adjusted to improve high current and voltage handling capability to suit the needs of a particular implementation without significantly affecting the overall height of integrated power assembly 442. In contrast to conventional power semiconductor packages having individual semiconductor dies arranged side by side and coupled to a substrate through their respective conductive clips, by stacking semiconductor die 468 over semiconductor die 478 on substrate 490, integrated power assembly 442 can advantageously have a reduced footprint, thereby reducing the form factor of integrated power assembly 442.

In an implementation, power switch 460 is cascoded with power switch 470 in integrated power assembly 442 to form an enhancement mode composite switch, where control electrode 466 (e.g., gate electrode) of power switch 460 is electrically coupled to power electrode 474 (e.g., source electrode) of power switch 470 through conductive trances (not explicitly shown in FIG. 4) on substrate 490. Integrated power assembly 442 can provide reduced form factor and enhanced thermal dissipation, while it can also substantially avoid increased parasitic inductance, thermal impedance, and assembly cost.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. An integrated power assembly comprising:
a printed circuit board;
a first leadframe having partially etched segments and non-etched segments on said printed circuit board;
a first semiconductor die configured for attachment to said partially etched segments of said first leadframe;
a second leadframe having a legless conductive clip;
a second semiconductor die situated over said first semiconductor die and being coupled to said first semiconductor die by said legless conductive clip.

2. The integrated power assembly of claim 1, wherein said second semiconductor die is coupled to said printed circuit board by a partially etched conductive clip of said second leadframe and at least one of said non-etched segments of said first leadframe.

3. The integrated power assembly of claim 1, wherein a drain electrode on said first semiconductor die is coupled to a source electrode on said second semiconductor die through said legless conductive clip.

4. The integrated power assembly of claim 1, wherein said first semiconductor die includes a first power transistor having a source electrode and a gate electrode at a bottom surface of said first semiconductor die, and a drain electrode on a top surface of said first semiconductor die.

5. The integrated power assembly of claim 1, wherein said second semiconductor die includes a second power transistor having a source electrode and a gate electrode at a bottom surface of said second semiconductor die, and a drain electrode on a top surface of said second semiconductor die.

6. The integrated power assembly of claim 1, wherein said second semiconductor die includes a second power transistor having a source electrode at a bottom surface of said second semiconductor die, and a drain electrode and a gate electrode on a top surface of said second semiconductor die.

7. The integrated power assembly of claim 1, wherein said first semiconductor die includes a first power transistor, and said second semiconductor die includes a second power transistor.

8. The integrated power assembly of claim 7, wherein at least one of said first power transistor and said second power transistor includes silicon.

9. The integrated power assembly of claim 7, wherein at least one of said first power transistor and said second power transistor includes gallium nitride (GaN).

10. The integrated power assembly of claim 1, wherein said first semiconductor die includes a synchronous transistor, and said second semiconductor die includes a control transistor coupled to said synchronous transistor in a half-bridge.

11. The integrated power assembly of claim 1, wherein said first semiconductor die includes a group IV transistor, and said second semiconductor die includes a group III-V transistor in cascode with said group IV transistor.

12. An integrated power assembly comprising:
a printed circuit board;
a first leadframe having partially etched segments and non-etched segments on said printed circuit board;
a first semiconductor die having a first power switch configured for attachment to said partially etched segments of said first leadframe;
a second leadframe having a legless conductive clip;
a second semiconductor die having a second power switch situated over said first semiconductor die, wherein a source electrode of said second power switch is coupled to a drain electrode of said first power switch by said legless conductive clip.

13. The integrated power assembly of claim 12, wherein said second semiconductor die is coupled to said printed circuit board by a partially etched conductive clip of said second leadframe and at least one of said non-etched segments of said first leadframe.

14. The integrated power assembly of claim 12, wherein at least one of said first power switch and said second power switch includes silicon.

15. The integrated power assembly of claim 12, wherein at least one of said first power switch and said second power switch includes gallium nitride (GaN).

16. The integrated power assembly of claim 12, said first power switch includes a synchronous transistor, and said second power switch includes a control transistor coupled to said synchronous transistor in a half-bridge.

17. The integrated power assembly of claim 12, wherein at least one of said first power switch and said second power switch is selected from the group consisting of a field-effect transistor (FET), an insulated gate bipolar transistor (IGBT) and a high electron mobility transistor (HEMT).

18. The integrated power assembly of claim 12, wherein at least one of said first power switch and said second power switch includes a silicon FET or a GaN FET.

19. The integrated power assembly of claim 12, wherein said partially etched segments of said first leadframe have a substantially uniform thickness.

20. The integrated power assembly of claim 12, wherein said legless conductive clip includes copper.
